(19) United States
(12) Patent Application Publication
(10) Pub. No.: US 2025/0259907 A1
(43) Pub. Date: Aug. 14, 2025

(54) DISTINGUISHED FLIP CHIP PACKAGING FOR STRESS RELAXATION AND ENHANCED EM PROTECTION

(71) Applicant: Applied Materials, Inc., Santa Clara, CA (US)

(72) Inventors: Akash Agrawal, San Jose, CA (US); Mudit Sunilkumar Khasgiwala, Milpitas, CA (US)

(73) Assignee: Applied Materials, Inc., Santa Clara, CA (US)

(21) Appl. No.: 18/437,569

(22) Filed: Feb. 9, 2024

(51) Int. Cl. H01L 23/373; H01L 23/00; H01L 23/31; H01L 23/552; H01L 25/065

(52) U.S. Cl. CPC H01L 23/3735; H01L 23/3121; H01L 23/552; H01L 24/13; H01L 24/29; H01L 25/0655; H01L 2224/13009; H01L 2224/13025; H01L 2224/29021; H01L 2224/2919; H01L 2924/01022; H01L 2924/01028; H01L 2924/01029; H01L 2924/18161; H01L 2924/3511

(57) ABSTRACT

Exemplary flip chip packages may include a carrier substrate. The packages may include a chiplet electrically and physically coupled with the carrier substrate via a plurality of interconnects. The packages may include an underfill positioned between the carrier substrate and the chiplet. The packages may include an epoxy molding coupled with the carrier substrate and covering an exposed surface of the chiplet. The packages may include a die attach film layer positioned about the chiplet. The die attach film layer may extend between and separates the chiplet and the carrier substrate. The die attach film layer may extend between and separates the chiplet and the epoxy molding. The die attach film layer may have a coefficient of thermal expansion of between 30 ppm/C and 35 ppm/C, inclusive. The die attach film layer may have a Young's modulus of between 4 GPa and 5 GPa, inclusive.

### TECHNICAL FIELD

The present technology relates to flip chip packages. More specifically, the present technology relates to package designs that reduce internal stresses within the packages.

### BACKGROUND

Flip chip packages are often used to interconnect semiconductor devices, such as integrated circuit (IC) chips and microelectromechanical systems (MEMS), with external circuitry using connections, such as solder bumps that have been deposited onto the chip pads. For example, the semiconductor devices may be flipped (or inverted) and positioned on the external circuitry such that the solder bumps or other connections are facing the connections on the external circuitry. The solder bumps may then be remelted to electrically couple the semiconductor device with the external circuitry.

Flip chip packages may have smaller form factors than conventional carrier-based packages, as the semiconductive device may sit directly on the external circuitry and the semiconductor devices are typically much smaller than the electronic circuitry. Additionally, the use of flip chip packages may reduce inductance of the resultant electronic component, as the inverted connection may reduce the length of wire needed to connect the semiconductor devices with the external circuitry. This may enable the resultant electronic component to facilitate higher-speed signals and to better conduct heat. However, conventional flip chip packages often exhibit higher stresses where different materials of the flip chip package meet due to differences in the coefficient of thermal expansion of the different materials. These higher stresses may result in failures in the package, such as delamination, cracking, interconnect failures, and the like.

Thus, there is a need for improved flip chip package designs that can be used to reduce stresses caused by mismatches in coefficients of thermal expansion of adjacent materials. These and other needs are addressed by the present technology.

### SUMMARY

Exemplary flip chip packages may include a carrier substrate. The packages may include a chiplet electrically and physically coupled with the carrier substrate via a plurality of interconnects. The packages may include an underfill positioned between the carrier substrate and the chiplet. The packages may include an epoxy molding coupled with the carrier substrate and covering an exposed surface of the chiplet. The packages may include a die attach film layer positioned about the chiplet. The die attach film layer may extend between and separate the chiplet and the epoxy molding. The die attach film layer may have a coefficient of thermal expansion of between 30 ppm/C and 35 ppm/C, inclusive. The die attach film layer may have a Young's modulus of between 4 GPa and 5 GPa, inclusive.

In some embodiments, the packages may include an electromagnetic interference (EMI) coating that extends between the die attach film layer and the epoxy molding. The EMI coating may include at least one of graphene, copper, nickel, titanium, cobalt, gold, silver, silicon, vanadium, or glass. The EMI coating may include an adhesion layer, a shield metal layer positioned atop the adhesion layer, and a cap layer positioned atop the shield metal layer. The adhesion layer may have a thickness of between 200 nm and 300 nm, inclusive. The shield metal layer may have a thickness of between 3 μm and 6 μm, inclusive. The cap layer may have a thickness of between 200 nm and 300 nm, inclusive. The EMI coating may include a metallic layer, a non-magnetic layer positioned atop the metallic layer, and a ferromagnetic layer positioned atop the non-magnetic layer. The chiplet may be a first chiplet. The flip chip packages may include a second chiplet stacked atop the first chiplet. The die attach film layer may extend between and separate the epoxy molding from the chiplet, the underfill, and the interconnects.

Some embodiments of the present technology may encompass flip chip packages that include a carrier substrate. The packages may include a plurality of chiplets. Each chiplet of the plurality of chiplets may be electrically and physically coupled with the carrier substrate via a respective plurality of interconnects. Chiplets of the plurality of chiplets may be spaced apart from another along a surface of the carrier substrate. The packages may include a plurality of underfills. Each underfill of the plurality of underfills may be positioned between the carrier substrate and a respective chiplet of the plurality of chiplets. The packages may include an epoxy molding coupled with the carrier substrate and covering an exposed surface of each of the plurality of chiplets. The packages may include a plurality of die attach film layers. Each die attach film layer of the plurality of die attach film layers may be positioned about a respective chiplet of the plurality of chiplets. Each die attach film layer may extend between and separate the respective chiplet and the epoxy molding. Each die attach film layer may have a coefficient of thermal expansion of between 30 ppm/C and 35 ppm/C, inclusive. Each die attach film layer may have a Young's modulus of between 4 GPa and 5 GPa, inclusive.

In some embodiments, the carrier substrate may include an organic substrate. The packages may include a plurality of electromagnetic interference (EMI) coatings. Each EMI coating of the plurality of EMI coatings may extend between the epoxy molding and a respective die attach film layer of the plurality of die attach film layers. Each of the plurality of EMI coatings may include multiple layers. Each of the plurality of EMI coatings may include at least one metallic layer. Each die attach film layer may extend between and separate the epoxy molding from the respective chiplet, a respective underfill, and the interconnects. At least one chiplet of the plurality of chiplets may be vertically stacked with an additional chiplet. Each die attach film layer may include a conductive material.

Some embodiments of the present technology may encompass methods of producing a flip chip package. The methods may include electrically and physically coupling a chiplet to a carrier substrate via a plurality of interconnects. The methods may include applying an underfill between the chiplet, the carrier substrate, and the plurality of interconnects. The methods may include applying a die attach film layer to an exposed surface of the chiplet. The die attach film layer may have a coefficient of thermal expansion of between 30 ppm/C and 35 ppm/C, inclusive. The die attach film layer may have a Young's modulus of between 4 GPa and 5 GPa, inclusive. The methods may include applying an epoxy molding to the carrier substrate that covers an exposed surface of the chiplet. The die attach film layer may extend between and separate the chiplet and the epoxy molding.

In some embodiments, the underfill may include an electrically-insulating adhesive. The plurality of interconnects may include solder bumps. Electrically and physically coupling the chiplet to the carrier substrate may include remelting the solder bumps to join electrical pads of the chiplet with electrical connectors of the carrier substrate. The methods may include applying an electromagnetic interference (EMI) coating to the die attach film layer. The EMI coating may be disposed between the die attach film and the epoxy molding.

Such technology may provide numerous benefits over conventional systems and techniques. For example, the flip chip packages may reduce the mismatch in coefficients of thermal expansion (CTE) of adjacent materials of the packages to reduce the stress the package is subjected to during temperature changes that occur during manufacturing and use. In particular, embodiments may introduce a low modulus die attach film layer between the silicon die, the underfill, the interconnects assembly, and epoxy molding. The die attach film layer may provide a stress buffer layer between different CTE materials and avoid high stress singularity locations. Embodiments may also include a stiff electromagnetic interference (EMI) protection layer formed atop the die attached film layer, which may protect the dies from electromagnetic effects and provide uniform stiff surface for epoxy molding. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic side elevation cross-sectional view of an exemplary flip chip package according to some embodiments of the present technology.

FIG. 2 shows a schematic side elevation cross-sectional view of an exemplary EMI coating according to some embodiments of the present technology.

FIG. 3 shows a schematic side elevation cross-sectional view of an exemplary EMI coating according to some embodiments of the present technology.

FIG. 4 operations of an exemplary method of producing a flip chip package according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Flip chip packages are often used to electrically and physically couple semiconductor devices, such as chiplets, with external circuitry, such as printed circuit boards. The flip chip packages may have smaller form factors than conventional carrier-based packages and may reduce inductance of the resultant electronic component. This may enable the resultant electronic component to facilitate higher-speed signals and to better conduct heat. However, while conventional flip chip packages provide several benefits over conventional carrier-based packages, there are still some drawbacks with conventional flip chip packages.

For example, conventional flip chip packages often exhibit higher stresses where different materials of the flip chip package meet due to large differences in the coefficient of thermal expansion (CTE) of the different materials. During manufacturing of flip chip packages, the various materials undergo thermocycling and reliability testing that mimic end-use performance. Additionally, during end-use operation, the flip chip packages undergo large temperature swings as the electronic components change operational states. These temperature fluctuations, in conjunction with the different CTEs of the materials making up the flip chip packages, result in generation of high stresses within the components of the flip chip packages, particularly at regions where materials with different CTEs meet. These high stresses may result in failures in the flip chip package, such as delamination, cracking, interconnect failures, and the like.

The present technology may address these problems by incorporating a die attach film layer that separates the chiplet, underfill, and interconnects from an epoxy molding that protects and insulates the chiplet from exposure to the environment. The die attach film layer may have a low Young's modulus, which may enable the die attach film layer to act as a stress buffer layer between materials (such as the semiconductor device, underfill, interconnects, epoxy molding, etc.) that have different CTEs. The low Young's modulus of the die attach film may enable the chiplet, underfill, and interconnects assembly to decouple from the epoxy molding, absorb expansion due to CTE mismatch, and provide a stress barrier zone which relaxes the rigid body structure and prevents failures. Some embodiments may also incorporate a stiff electromagnetic interference (EMI) protection layer on the top of the die attach film layer that may protect the chiplets from electromagnetic effects and provide uniform stiff surface for the epoxy molding.

Although the remaining disclosure will routinely identify specific structures, such as flip chip package designs, for which the present structures and methods may be employed, it will be readily understood that the systems and methods are equally applicable to any number of structures and devices that may benefit from the structural capabilities explained. Accordingly, the technology should not be considered to be so limited as for use with any particular structures alone.

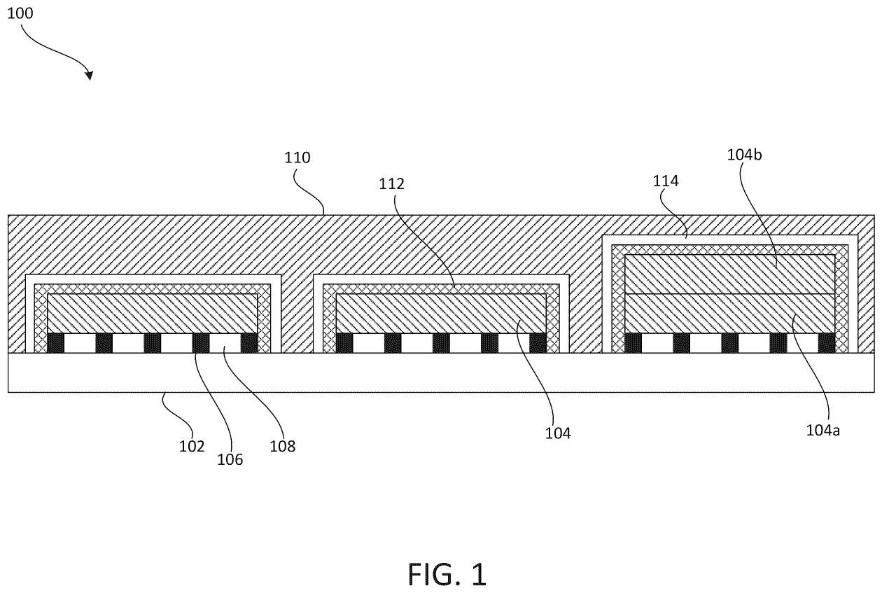

FIG. 1 shows a schematic cross-sectional view of an exemplary flip chip package 100 according to some embodiments of the present technology. The flip chip package 100 may include a carrier substrate 102, which may include external circuitry in some embodiments. For example, the carrier substrate 102 may be a printed circuit board (PCB) and/or other substrate on which one or more circuits and/or electrical components are formed and/or mounted. In some embodiments, the carrier substrate 102 may be an organic substrate, such as a silicon substrate. The carrier substrate 102 may include any number of circuits and/or electrical components. For example, the carrier substrate 102 may include at least one circuit (or electrical component), at least two circuits, at least three circuits, at least four circuits, at least six circuits, at least eight circuits, at least 10 circuits, at least 20 circuits, or more.

The flip chip package 100 may include one or more chiplets 104 that may be mounted on the carrier substrate 102. Each chiplet 104 may be a die, such as a semiconductor device, an integrated circuit (IC) chip, a microelectromechanical systems (MEMS) device, and/or other component. Each chiplet 104 may be electrically and physically coupled with the carrier substrate 102, such as by being coupled with one or more of the circuits or other electrical components on the carrier substrate 102. For example, each chiplet 104 may include one or more electrically conductive pads that serve as electrical contacts for the chiplet 104. A number of interconnects 106, such as solder bumps and/or other electrical contacts, may be formed on and/or otherwise coupled with the electrically conductive pads and electrical contacts of the circuits of the carrier substrate 102 to join the electrically conductive pads of the chiplet 104 with the electrical contacts of the carrier substrate 102. In some embodiments, each chiplet 104 may be coupled with a single circuit of the carrier substrate 102, while in other embodiments one or more of the chiplets 104 may be coupled with multiple circuits of the carrier substrate 102. While shown with three chiplets 104, the flip chip package 100 may include any number chiplets 104. For example, the flip chip package 100 may include one or more chiplets, two or more chiplets, three or more chiplets, four or more chiplets, five or more chiplets, 10 or more chiplets, 20 or more chiplets, or more. Each chiplet 104 may be a same type/structure of die and/or the flip chip package 100 may include multiple types of chiplets. Where multiple chiplets 104 are provided, some or all of the chiplets 104 may be spaced apart from another along a surface of the carrier substrate 102.

The flip chip package 100 may include one or more underfills 108, with each underfill 108 being positioned between the carrier substrate 102 and one of the chiplets 104. For example, each underfill 108 may extend between and fill (or partially fill) the volume between one of the chiplets 104 and the carrier substrate 102. The underfill 108 may extend between the various interconnects that couple the carrier substrate 102 with the chiplet 104. The underfill 108 may help increase the strength and stability of the connection between the chiplet 104 and the carrier substrate 102, such as by providing structure between the two components of the flip chip package 100. In some embodiments, the underfill 108 may be an electrically insulating adhesive and/or epoxy thermoset that may fill the voids and between and isolate the various interconnects 106 from one another, while also helping to hold the chiplet 104 to the carrier substrate 102.

The flip chip package 100 may include an epoxy molding 110 that may be coupled with the carrier substrate 102 and may cover one or more exposed surfaces of the chiplets 104 (e.g., one or more surfaces of each chiplet 104 that do not face the carrier substrate 102). The epoxy molding 110 may cover all (or substantially all) of the exposed surface area of the chiplet 104 and may contact and be bonded to a surface of the carrier substrate 102. The epoxy molding 110 may provide environmental and structural protection for the chiplets 104. In some embodiments, the epoxy molding 110 may be continuous and may cover all chiplets 104 that are coupled with the carrier substrate 102. In other embodiments, one or more of the chiplets 104 may be covered by a discrete piece of epoxy molding 110.

The flip chip package 100 may include a die attach film layer 112 positioned about each chiplet 104. In other words, each chiplet 104 may include a dedicated die attach film layer 112. Each die attach film layer 112 may extend between and separate a given chiplet 104 from the epoxy molding 110. For example, the exposed surfaces (e.g., each surface of a chiplet 104 that do not face the carrier substrate 102) of each chiplet 104 may be covered by a die attach film layer 112 such that the die attach film layer 112 separates the chiplet 104 from the epoxy molding 110. This enables the die attach film layer 112 to form a stress buffer layer that reduces the stresses that would otherwise be exhibited at junctions of the epoxy molding 110 and the chiplet 104 and/or other components of the flip chip package 100. For example, the die attach film layer 112 may extend between and separate the epoxy molding 110 from a given chiplet 104 and the associated underfill 108 and interconnects 106 such that the epoxy molding 110 only contacts the carrier substrate 102 and the die attach film layer 112. This may enable the die attach film layer 112 to also form a stress buffer layer that reduces the stresses that would otherwise be exhibited at junctions of the epoxy molding 110 and the interconnects 106/underfill 108, particular during temperature changes.

To effectively serve as a stress buffer layer, the die attach film layer 112 may be selected to have certain properties. For example, the die attach film layer 112 may have a coefficient of thermal expansion (CTE) of between 10 ppm/° C. and 55 ppm/° C., between 20 ppm/° C. and 45 ppm/° C., or between 30 ppm/° C. and 35 ppm/° C., inclusive, although materials having a CTE outside of these ranges may be used in some embodiments. The die attach film layer 112 may have a Young's modulus of between 3 GPa and 6 GPa, between 3.5 GPa and 5.5 GPa, or between 4 GPa and 5 GPa, inclusive. The use of a relatively low Young's modulus keeps the die attach film layer 112 sufficiently soft and deformable to enable the components shielded by the die attach film layer 112 (e.g., the chiplet 104, interconnects 106, and/or underfill 108) to be decoupled from the epoxy molding 110, to absorb expansion due to CTE mismatch between the epoxy molding 110 and relative component material, and to provide a stress barrier zone which relaxes the rigid body structure and prevents failures such as delamination and cracking. In a particular embodiment, the die attach film layer 112 may include an organic resin, such as a thermoplastic or thermoset material having a Young's modulus in the ranges described above. In some embodiments, the die attach film layer 112 may include one or more electrically conductive materials, such as silver. In other embodiments, the die attach film layer 112 may be a non-electrically conductive layer.

In some embodiments, the flip chip package 100 may include an electromagnetic interference (EMI) coating 114 or layer that extends between and separates the die attach film layer 112 and the epoxy molding 110. For example, each chiplet 104 may include a dedicated die attach film layer 112 and EMI coating 114. The EMI coating 114 may be a stiff layer that protects the chiplets 104 from electromagnetic effects and that may provide a uniform and stiff surface for the epoxy molding 110. The EMI coating 114 may cover the exposed surfaces of the die attach film layer 112 and may contact the carrier substrate 102 such that the die attach film layer 112 is fully separated from the epoxy molding 110 in some embodiments.

As noted above, the EMI coating 114 may protect the chiplets 104 from electromagnetic effects. To provide this protection, the EMI coating 114 may include at least one shielding material, which may be a metallic/conductive material and/or an insulator, which may be selected to shield the chiplets 104 from different frequency ranges. For example, the EMI coating 114 may include graphene, copper, nickel, titanium, cobalt, gold, silver, silicon, vanadium, glass, and/or other materials in various embodiments. In some embodiments, the EMI coating 114 may include at least one metallic layer, however multi-layer designs that include multiple shielding materials (e.g., multiple metallic layers, multiple insulator layers, and/or combinations thereof) may be designed to shield the chiplets 104 over a larger range of frequencies.

In some embodiments, one or more of the chiplets 104 may be vertically stacked with another chiplet. For example, chiplet 104a is stacked with a second chiplet 104b prior to the application of the die attach film layer 112 and/or epoxy molding 110. It will be appreciated that any number of chiplets 104 may be vertically stacked with one another, with the stacked chiplets 104 being electrically coupled and/or isolated from one another. In some embodiments, the vertically stacked chiplets 104 may include an adhesive that couples the stacked chiplets 104 together. Additionally, while shown with only one stack of vertically stacked chiplets 104, it will be appreciated that any number (including all) chiplets 104 on the flip chip package 100 may be part of vertical stacks in some embodiments. Vertically stacked chiplets 104 may have dedicated and/or shared die attach film layers 112 in various embodiments.

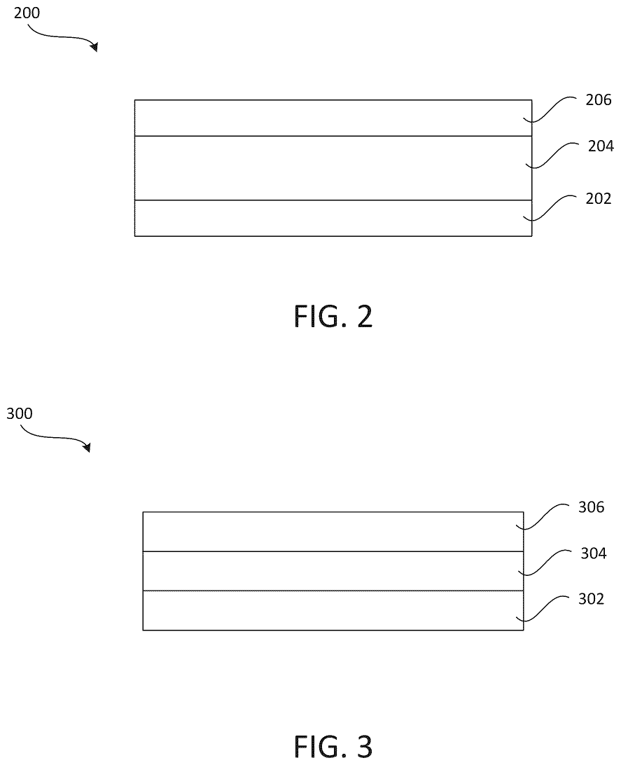

FIG. 2 shows a schematic cross-sectional view of an exemplary EMI coating 200 according to some embodiments of the present technology. EMI coating 200 may be used as EMI coating 114 in some embodiments and may include any features described in relation to EMI coating 114. As illustrated, EMI coating 200 includes an adhesion layer 202 that is used to adhere the EMI coating 200 to the surface of an object, such as chiplet 104 and/or die attach film layer 112. The adhesion layer 202 may have a thickness of between 100 nm and 500 nm, between 150 nm and 400 nm, or between 200 nm and 300 nm, inclusive. The EMI coating 200 may include at least one shield metal layer 204 positioned atop and/or otherwise against the adhesion layer 202. The shield metal layer 204 may include one or more shield materials (such as those listed above) and may provide EMI shielding properties. While called a metal layer, it will be appreciated that one or more of the shield metal layers 204 may be formed from non-metallic materials. Collectively, the shield metal layers 204 may have a thickness of between 1 μm and 10 μm, between 2 μm and 8 μm, or between 3 μm and 6 μm, inclusive. The EMI coating 200 may include a cap layer 206 positioned atop and/or otherwise against an uppermost shield metal layer 204. The cap layer 206 may protect the shield metal layers 204 (and in particular, the uppermost shield metal layer 204) from oxidation and/or damage. The cap layer 206 may have a thickness of between 100 nm and 500 nm, between 150 nm and 400 nm, or between 200 nm and 300 nm, inclusive. The total thickness of the EMI coating 200 may be between 1.2 μm and 11 μm in some embodiments, although other thicknesses are possible. Additional layers may be included in the EMI coating 200 in some embodiments.

FIG. 3 shows a schematic cross-sectional view of an exemplary EMI coating 300 according to some embodiments of the present technology. EMI coating 300 may be used as EMI coating 114 in some embodiments and may include any features described in relation to EMI coating 114 and/or EMI coating 200 described above. EMI coating 300 may include one or more metallic layers 302 that may be positioned and/or adhered to the surface of an object, such as chiplet 104 and/or die attach film layer 112. Each metallic layer 302 may include a metallic material that is selected to shield a chiplet from a particular range of frequencies. One or more non-magnetic layers 304 may be positioned atop and/or otherwise against the metallic layers 302. The non-magnetic layers 304 may each include one or more non-magnetic materials (possibly including insulators) that may be selected to shield against a different range of frequencies to expand the overall shielding range of the EMI coating 300. The EMI coating 300 may also include one or more ferromagnetic layers 306, which may be positioned atop and/or otherwise against the non-magnetic layers 304. The combination of metallic, non-magnetic, and/or ferromagnetic layers may enable the EMI coating 300 to provide low-frequency shielding and/or shielding across a wide range of frequencies relative to the use of a single shield material. For example, more conductive materials may provide better shielding at high frequencies, while magnetic materials offer shielding at lower frequencies. Additional layers, including adhesive and/or cap layers, may be included in the EMI coating 300 in some embodiments. As just one example, one or more (possibly all) layers of EMI coating 300 may be used at the shield metal layer 204 of EMI coating 200 in some embodiments. In some embodiments, the materials of the EMI coatings described herein may be selected to minimize CTE mismatch between different layers, which may help better dissipate heat without delaminating and/or otherwise damaging the EMI coating. In some embodiments, rather than (or in addition to) the use of an EMI coating, other stiffening layers may be positioned against the die attach film layer 112 to provide a stiff base to support the epoxy molding.

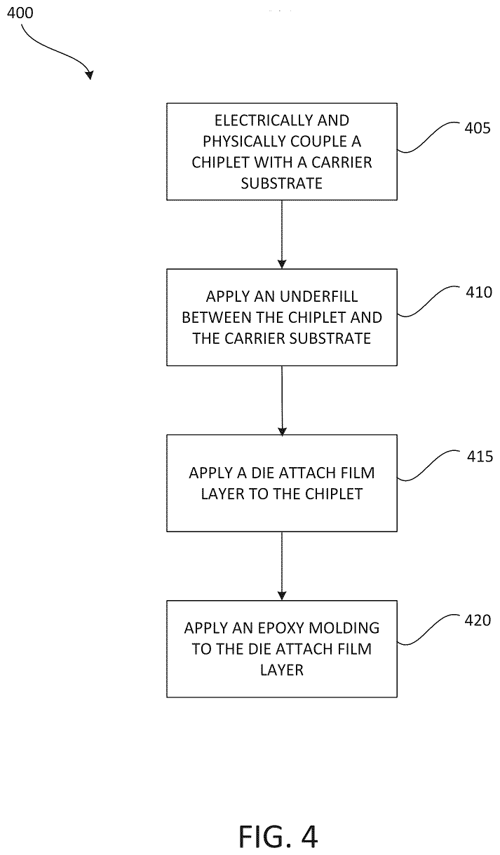

FIG. 4 shows operations of an exemplary method 400 of producing a flip chip package according to some embodiments of the present technology. The method may be performed to produce a variety of flip chip packages including flip chip package 100 described above, which may include die attach film layers (such as die attach film layer 112) and/or EMI coatings (such as EMI coating 114, 200, and/or 300) according to embodiments of the present technology. Method 400 may include a number of optional operations, which may or may not be specifically associated with some embodiments of methods according to the present technology.

Method 400 may include a production method that may include operations for coupling one or more chiplets to a carrier substrate to form a flip chip package. The method may include optional operations prior to initiation of method 400, or the method may include additional operations. For example, method 400 may include operations performed in different orders than illustrated. Method 400 may include electrically and physically coupling a chiplet (or multiple chiplets) to a carrier substrate via a plurality of interconnects at operation 405. For example, the interconnects may be solder bumps that have been formed on electrically conductive pads on a surface (such as a top surface) of the chiplet. The solder bumps may be remelted to join the electrical pads of the chiplet with electrical connectors (such as connectors for one or more circuits) of the carrier substrate. For example, where the electrical pads of the chiplet are formed on an upper surface of the chiplet, the chiplet may be inverted such that the upper surface (as well as electrical pads and solder bumps) face a surface of the carrier substrate. The solder bumps may be remelted such that the solder may extend between and join the electrical pads and electrical connectors.

At operation 410, an underfill, such as an epoxy thermoset and/or insulating adhesive material, may be applied between the chiplet, the carrier substrate, and the plurality of interconnects. A die attach film layer may be applied to an exposed surface of the chiplet at operation 415. The die attach film layer may have a coefficient of thermal expansion of between 10 ppm/C and 55 ppm/C, inclusive and/or may have a Young's modulus of between 3 GPa and 6 GPa, inclusive. At operation 420, an epoxy molding may be applied to the carrier substrate that covers an exposed surface of the chiplet. The die attach film layer may extend between and separate the chiplet and the epoxy molding (and possibly separate the epoxy molding from the underfill and/or interconnects) to act as a stress buffer layer that may enable the chiplet, underfill, and/or interconnects assembly to decouple from the epoxy molding, absorb expansion due to CTE mismatch, and provide a stress barrier zone which relaxes the rigid body structure and prevents failures. In some embodiments, prior to applying the epoxy molding, the process may include applying an electromagnetic interference (EMI) coating to the die attach film layer such that the EMI coating may be disposed between the die attach film and the epoxy molding. The EMI coating may protect the chiplets 104 from electromagnetic effects and may provide a uniform and stiff surface for the epoxy molding.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a chiplet” includes a plurality of such chiplets, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A flip chip package, comprising:
a carrier substrate;
a chiplet electrically and physically coupled with the carrier substrate via a plurality of interconnects;
an underfill positioned between the carrier substrate and the chiplet;
an epoxy molding coupled with the carrier substrate and covering an exposed surface of the chiplet; and
a die attach film layer positioned about the chiplet, wherein:
the die attach film layer extends between and separates the chiplet and the epoxy molding;
the die attach film layer has a coefficient of thermal expansion of between 30 ppm/C and 35 ppm/C, inclusive; and
the die attach film layer has a Young's modulus of between 4 GPa and 5 GPa, inclusive.

2. The flip chip package of claim 1, further comprising:
an electromagnetic interference (EMI) coating that extends between the die attach film layer and the epoxy molding.

3. The flip chip package of claim 2, wherein:
the EMI coating comprises at least one of graphene, copper, nickel, titanium, cobalt, gold, silver, silicon, vanadium, or glass.

4. The flip chip package of claim 2, wherein:
the EMI coating comprises:
an adhesion layer;
a shield metal layer positioned atop the adhesion layer; and
a cap layer positioned atop the shield metal layer.

5. The flip chip package of claim 4, wherein:
the adhesion layer has a thickness of between 200 nm and 300 nm, inclusive;
the shield metal layer has a thickness of between 3 μm and 6 μm, inclusive; and
the cap layer has a thickness of between 200 nm and 300 nm, inclusive.

6. The flip chip package of claim 2, wherein:
the EMI coating comprises:
a metallic layer;
a non-magnetic layer positioned atop the metallic layer; and
a ferromagnetic layer positioned atop the non-magnetic layer.

7. The flip chip package of claim 1, wherein:
the chiplet comprises a first chiplet; and
the flip chip package further comprises a second chiplet stacked atop the first chiplet.

8. The flip chip package of claim 1, wherein:
the die attach film layer extends between and separates the epoxy molding from the chiplet, the underfill, and the interconnects.

9. A flip chip package, comprising:
a carrier substrate;
a plurality of chiplets, wherein:
each chiplet of the plurality of chiplets is electrically and physically coupled with the carrier substrate via a respective plurality of interconnects; and
chiplets of the plurality of chiplets are spaced apart from another along a surface of the carrier substrate;
a plurality of underfills, wherein each underfill of the plurality of underfills is positioned between the carrier substrate and a respective chiplet of the plurality of chiplets;
an epoxy molding coupled with the carrier substrate and covering an exposed surface of each of the plurality of chiplets; and
a plurality of die attach film layers, wherein:
each die attach film layer of the plurality of die attach film layers is positioned about a respective chiplet of the plurality of chiplets;
each die attach film layer extends between and separates the respective chiplet and the epoxy molding;
each die attach film layer has a coefficient of thermal expansion of between 30 ppm/C and 35 ppm/C, inclusive; and
each die attach film layer has a Young's modulus of between 4 GPa and 5 GPa, inclusive.

10. The flip chip package of claim 9, wherein:
the carrier substrate comprises an organic substrate.

11. The flip chip package of claim 9, further comprising:
a plurality of electromagnetic interference (EMI) coatings, wherein each EMI coating of the plurality of EMI coatings extends between the epoxy molding and a respective die attach film layer of the plurality of die attach film layers.

12. The flip chip package of claim 11, wherein:
each of the plurality of EMI coatings comprises multiple layers.

13. The flip chip package of claim 11, wherein:
each of the plurality of EMI coatings comprises at least one metallic layer.

14. The flip chip package of claim 9, wherein:
each die attach film layer extends between and separates the epoxy molding from the respective chiplet, a respective underfill, and the interconnects.

15. The flip chip package of claim 9, wherein:
at least one chiplet of the plurality of chiplets is vertically stacked with an additional chiplet.

16. The flip chip package of claim 9, wherein:
each die attach film layer comprises a conductive material.

17. A method of producing a flip chip package, comprising:
electrically and physically coupling a chiplet to a carrier substrate via a plurality of interconnects;
applying an underfill between the chiplet, the carrier substrate, and the plurality of interconnects;
applying a die attach film layer to an exposed surface of the chiplet, wherein:
the die attach film layer has a coefficient of thermal expansion of between 30 ppm/C and 35 ppm/C, inclusive; and
the die attach film layer has a Young's modulus of between 4 GPa and 5 GPa, inclusive; and
applying an epoxy molding to the carrier substrate that covers an exposed surface of the chiplet, wherein the die attach film layer extends between and separates the chiplet and the epoxy molding.

18. The method of producing a flip chip package of claim 17, wherein:
the underfill comprises an electrically-insulating adhesive.

19. The method of producing a flip chip package of claim 17, wherein:
the plurality of interconnects comprise solder bumps; and
electrically and physically coupling the chiplet to the carrier substrate comprises remelting the solder bumps to join electrical pads of the chiplet with electrical connectors of the carrier substrate.

20. The method of producing a flip chip package of claim 17, further comprising:
applying an electromagnetic interference (EMI) coating to the die attach film layer, wherein the EMI coating is disposed between the die attach film and the epoxy molding.
